(19) United States
(12) Patent Application Publication
(10) Pub. No.: US 2007/0036890 A1
(43) Pub. Date: Feb. 15, 2007

(54) Method of making a fuel cell component using a mask

(76) Inventors: Feng Zhong, Windsor (CA); Richard H. Blunk, Macomb Township, MI (US); Daniel J. Lisi, Eastpointe, MI (US)

Correspondence Address: CARY W. BROOKS;General Motors Corporation, Legal Staff, Mail Code 482-C23-B21, P.O. Box 300, Detroit, MI, 48265-3000, US

(21) Appl. No.: 11/259,391

(22) Filed: Oct. 26, 2005

Related U.S. Application Data
(60) Provisional application No. 60/707,692, filed on Aug. 12, 2005.

(51) Int. Cl. B05D 5/12; C23C 16/00; H05H 1/24; B05D 7/00; B05D 1/28

(52) U.S. Cl. 427/115; 427/282; 427/523; 427/372.2; 427/429; 427/421.1; 427/248.1; 427/430.1; 427/569

(57) ABSTRACT

A method of making a fuel cell component using a mask.

### CROSS REFERENCE TO RELATED APPLICATION

This application claims priority to U.S. Provisional Application Ser. No. 60/707,692, filed Aug. 12, 2005, the entire specification of which is expressly incorporated herein by reference.

### FIELD OF THE INVENTION

The present invention relates to a method of making a fuel cell component using a mask.

### BACKGROUND OF THE INVENTION

Hydrogen is a very attractive fuel because it is clean and can be used to efficiently produce electricity in a fuel cell. The automotive industry expends significant resources in the development of hydrogen fuel cells as a source of power for vehicles. Such vehicles would be more efficient and generate fewer emissions than today's vehicles employing internal combustion engines.

A hydrogen fuel cell is an electrochemical device that includes an anode and a cathode with an electrolyte therebetween. The anode receives hydrogen gas and the cathode receives oxygen or air. The hydrogen gas is dissociated in the anode to generate free protons and electrons. The protons pass through the electrolyte to the cathode. The protons react with the oxygen and the electrons in the cathode to generate water. The electrons from the anode cannot pass through the electrolyte, and thus are directed through a load to perform work before being sent to the cathode. The work acts to operate the vehicle.

Proton exchange membrane fuel cells (PEMFC) are a popular fuel cell for vehicles. The PEMFC generally includes a solid-polymer-electrolyte proton-conducting membrane, such as a perfluorosulfonic acid membrane. The anode and cathode typically include finely divided catalytic particles, usually platinum (Pt), supported on carbon particles and mixed with an ionomer. The catalytic mixture is deposited on opposing sides of the membrane. The combination of the anode catalytic mixture, the cathode catalytic mixture and the membrane define a membrane electrode assembly (MEA). MEAs are relatively expensive to manufacture and require certain conditions for effective operation. These conditions include proper water management and humidification, and control of catalyst poisoning constituents, such as carbon monoxide (CO).

Several fuel cells are typically combined in a fuel cell stack to generate the desired power. For the automotive fuel cell stack mentioned above, the stack may include about two hundred bipolar plates. The fuel cell stack receives a cathode reactant gas, typically a flow of air forced through the stack by a compressor. Not all of the oxygen is consumed by the stack and some of the air is output as a cathode exhaust gas that may include water as a stack by-product. The fuel cell stack also receives an anode hydrogen reactant gas that flows into the anode side of the stack.

The fuel cell stack includes a series of flow field or bipolar plates positioned between the several MEAs in the stack. The bipolar plates include an anode side and a cathode side for adjacent fuel cells in the stack. Anode gas flow channels are provided on the anode side of the bipolar plates that allow the anode gas to flow to the anode side of the MEA. Cathode gas flow channels are provided on the cathode side of the bipolar plates that allow the cathode gas to flow to the cathode side of the MEA. The bipolar plates may also include flow channels through which a cooling fluid flows.

The bipolar plates are typically made of a conductive material, such as stainless steel, titanium, aluminum, polymeric carbon composites, etc., so that they conduct the electricity generated by the fuel cells from one cell to the next cell and out of the stack. Metal bipolar plates typically produce a natural oxide on their outer surface that makes them resistant to corrosion. However, the oxide layer is not conductive, and thus increases the internal resistance of the fuel cell, reducing its electrical performance. Also, the oxide layer makes the plate more hydrophobic.

US Patent Application Publication No. 2003/0228512, assigned to the assignee of this application and herein incorporated by reference, discloses a process for depositing a conductive outer layer on a flow field plate that prevents the plate from oxidizing and increasing its ohmic contact. U.S. Pat. No. 6,372,376, also assigned to the assignee of this application, discloses depositing an electrically conductive, oxidation resistant and acid resistant coating on a flow field plate. US Patent Application Publication No. 2004/0091768, also assigned to the assignee of this application, discloses depositing a graphite and carbon black coating on a flow field plate for making the flow field plate corrosion resistant, electrically conductive and thermally conductive.

As is well understood in the art, the membranes within a fuel cell need to have a certain relative humidity so that the ionic resistance across the membrane is low enough to effectively conduct protons. During operation of the fuel cell, moisture from the MEAs and external humidification may enter the anode and cathode flow channels. At low cell power demands, typically below 0.2 A/cm², water accumulates within the flow channels because the flow rate of the reactant gas is too low to force the water out of the channels. As the water accumulates, it forms droplets that continue to expand because of the hydrophobic nature of the plate material. The contact angle of the water droplets is generally about 90° in that the droplets form in the flow channels substantially perpendicular to the flow of the reactant gas. As the size of the droplets increases, the flow channel is closed off, and the reactant gas is diverted to other flow channels because the channels flow in parallel between common inlet and outlet manifolds. Because the reactant gas may not flow through a channel that is blocked with water, the reactant gas cannot force the water out of the channel. Those areas of the membrane that do not receive reactant gas as a result of the channel being blocked will not generate electricity, thus resulting in a non-homogenous current distribution and reducing the overall efficiency of the fuel cell. As more and more flow channels are blocked by water, the electricity produced by the fuel cell decreases, where a cell voltage potential less than 200 mV is considered a cell failure. Because the fuel cells are electrically coupled in series, if one of the fuel cells stops performing, the entire fuel cell stack may stop performing.

It is usually possible to purge the accumulated water in the flow channels by periodically forcing the reactant gas through the flow channels at a higher flow rate. However, on the anode side, this increases the parasitic power applied to the air compressor, thereby reducing overall system efficiency. Moreover, there are many reasons not to use the hydrogen fuel as a purge gas, including reduced economy, reduced system efficiency and increased system complexity for treating elevated concentrations of hydrogen in the exhaust gas stream.

Reducing accumulated water in the channels can also be accomplished by reducing inlet humidification. However, it is desirable to provide some relative humidity in the anode and cathode reactant gases so that the membrane in the fuel cells remains hydrated. A dry inlet gas has a drying effect on the membrane that could increase the cell's ionic resistance, and limit the membrane's long-term durability.

It has been proposed by the present inventors to make bipolar plates for a fuel cell hydrophilic to improve channel water transport. A hydrophilic plate causes water in the channels to form a thin film that has less of a tendency to alter the flow distribution along the array of channels connected to the common inlet and outlet headers. If the plate material is sufficiently wettable, water transport through the diffusion media will contact the channel walls and then, by capillary force, be transported into the bottom corners of the channel along its length. The physical requirements to support spontaneous wetting in the corners of a flow channel are described by the Concus-Finn condition,

$$β + \frac{α}{2} < 90 \underline{°} ,$$

where β is the static contact angle and α is the channel corner angle. For a rectangular channel α/2=45°, which dictates that spontaneous wetting will occur when the static contact angle is less than 45°. For the roughly rectangular channels used in current fuel cell stack designs with composite bipolar plates, this sets an approximate upper limit on the contact angle needed to realize the beneficial effects of hydrophilic plate surfaces on channel water transport and low load stability.

### SUMMARY OF THE INVENTION

One embodiment of the invention is a method of making a fuel cell component using a mask. The mask may be a hard mask or a photoresist mask.

Other embodiments of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 illustrates a substrate useful in making a fuel cell component according to one embodiment of the invention;

FIG. 2 illustrates a process according to one embodiment of the invention including depositing a photoresist material of a substrate;

FIG. 3 illustrate a process according to one embodiment of the invention including exposing the photoresist material;

FIG. 4 illustrate a process according to one embodiment of the invention including removing portions of the photoresist material;

FIG. 5 illustrates a process according to one embodiment of the invention including depositing a coating in the opening between adjacent portions of the remaining photoresist material;

FIG. 6 illustrates a process according to one embodiment of the invention including removing the remaining photoresist material and forming the substrate into a bipolar plate;

FIG. 7 illustrates a process according to one embodiment of the invention including depositing a photoresist material over a bipolar plate;

FIG. 8 illustrates a process according to one embodiment of the invention including removing portions of the photoresist over the channels and leaving portions of the photoresist over the lands of the bipolar plate;

FIG. 9 illustrates a process according to one embodiment of the invention including depositing a coating over the remaining photoresist material and into the channels; and

FIG. 10 illustrates a process according to one embodiment of the invention including removing the mask and the coating over the mask to leave the coating in the channels.

### DETAILED DESCRIPTION OF PREFERRED EMBODIMENTS

The following description of the preferred embodiment(s) is merely exemplary in nature and is in no way intended to limit the invention, its application, or uses.

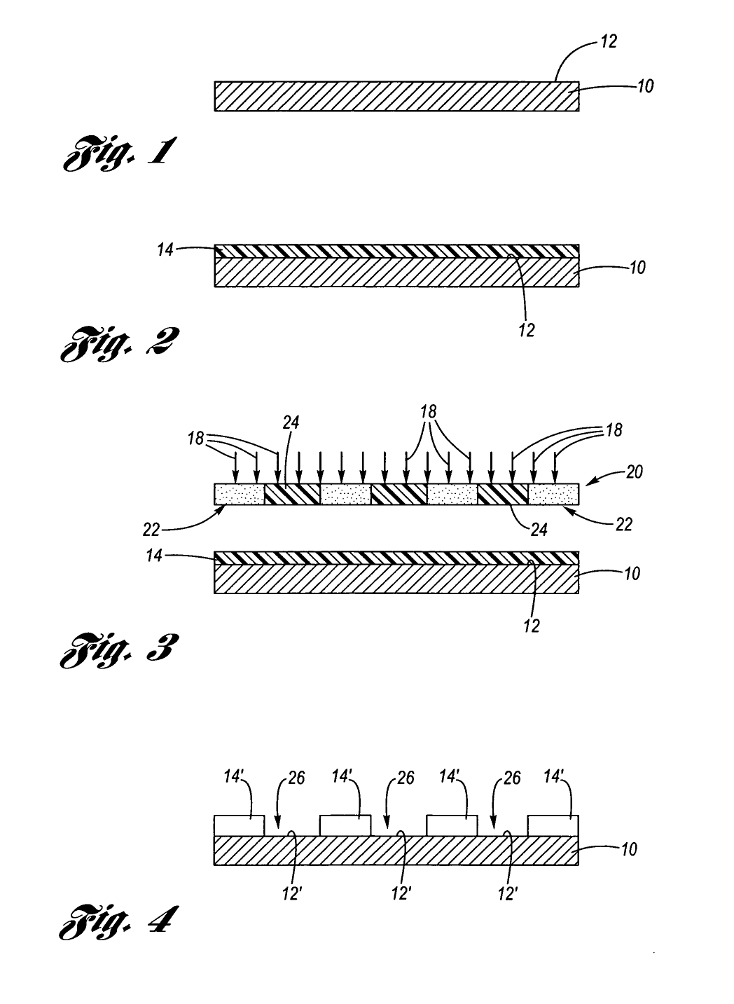

FIG. 1 illustrates a substrate 10 useful in making a fuel cell component such as, but not limited to, a bipolar plate. The substrate 10 is substantially flat and includes an upper surface 12.

Referring now to FIG. 2, one embodiment of the invention, a photoresist material 14 is deposited over the upper surface 12 of the substrate 10. The photoresist 14 may be spun on or deposited as a decal. The photoresist material 14 may be a negative or positive photoresist.

Referring now to FIG. 3, a rectile 20 is positioned over the photoresist material 14. The rectile 20 include light transmitting potions 22 and light blocking portions 24. Energy, for example from ultraviolet light, is selectively transmitted through the rectile 20 and onto the photoresist material 14. The energy will cause portions of the photoresist to either be easily removed or not removable by the developer depending on whether the photoresist material 14 is a positive or negative photoresist. The hydrophilic coating 28 may, in one embodiment of the invention, include inorganic and organic structures. Examples of suitable hydrophilic coatings include, but are not limited to, coatings including metal oxides, including SiO₂, HfO₂, ZrO₂, Al₂O₃, SnO₂, Ta₂O₅, Nb₂O₅, MoO₂, IrO₂, RuO₂, metastable oxynitrides, nonstoichiometric metal oxides, oxynitrides, and derivatives thereof including carbon chains or including carbon and/or polar groups, and mixtures thereof. The coating 16 may be depositing by spraying, brushing, rolling, printing, dipping, physical vapor deposition, chemical vapor deposition or plasma assisted vapor deposition.

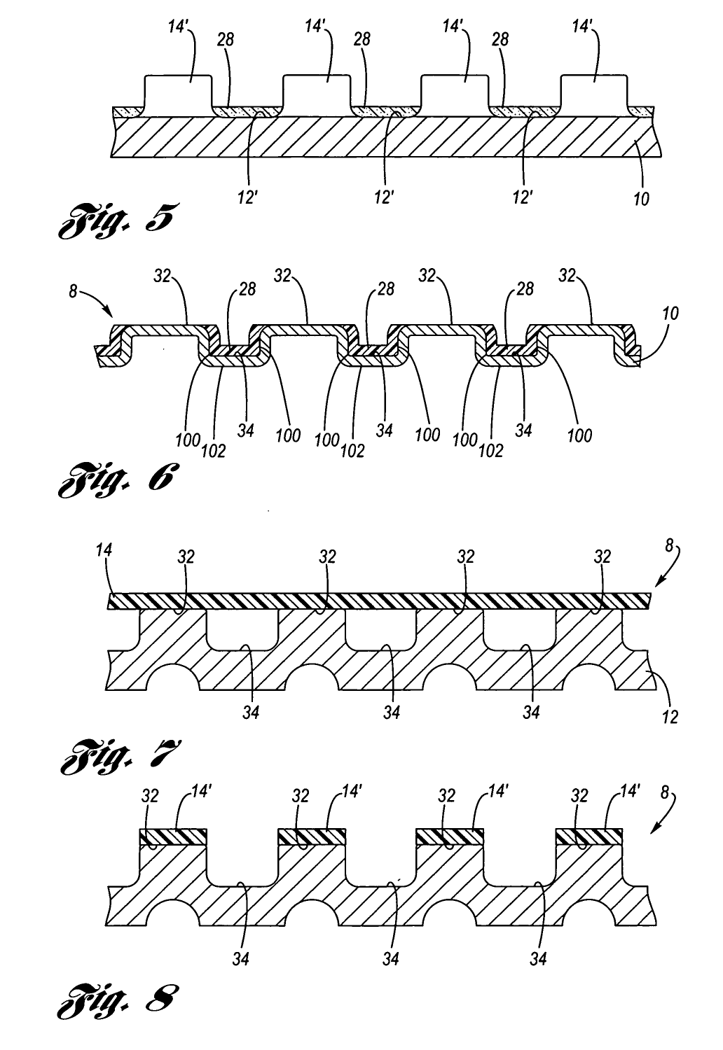

Referring now to FIG. 4., the photoresist material 14 is then developed, for example using potassium carbonate and uncrossed linked portions of the photoresist are removed leaving portions 12′ of the upper surface 12 of the substrate 10 exposed. Work may be performed on the exposed portion 12′ of the upper surface 12. The work may include, but is not limited to, cleaning, etching, pitting, ion implanting, bombarding, doped, blasting or coating the exposed portion 12′ of the upper surface. The space between adjacent section of the remaining photoresist material 14′ may form a channel 26.

Referring now to FIG. 5, in one embodiment of the invention a coating 28, such as a hydrophilic coating, is flown through the channel 26 between adjacent portions of the remaining photoresist 14′ and the coating is cured. As an alternative embodiment, the mask may be a hard mask such as a metal, plastic or magnetize material and may be shaped in a configuration like the remaining portions 14′ of the photoresist material.

Revering now to FIG. 6, after the remaining portions 14′ of the photoresist are removed, for example by stripping with a fluid such comprising, 2-hydroethylaime, and tetramethyammonium hydroxide. The substrate 10 can be formed into a fuel cell component such as a bipolar plate 8. The forming may be done by stamping or the like. The bipolar plate 8 includes lands 32 and channels 34. Preferably the coating 28 is only in the channels 34 of the bipolar plate 8. The channels 34 of the bipolar plate 8 may be defined by side walls 100 and a floor 102. the coating may be on the side walls 100 and floor 102, or only on the floor 102.

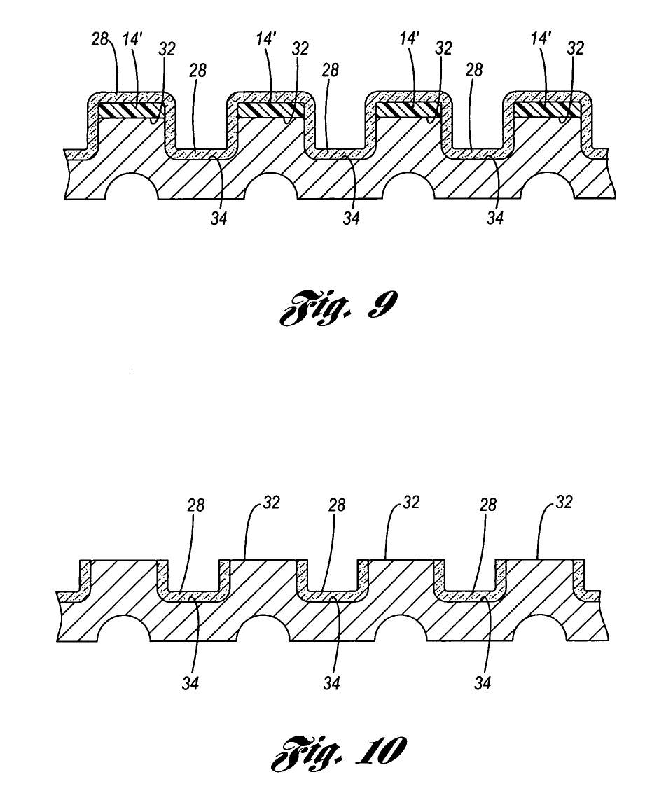

Referring now to FIG. 7, in another embodiment of the invention, a photoresist material 14 is deposited over a bipolar plate 8 and rest on the lands 32 of the bipolar plate 8. The photoresist material 14 is patterned, developed and portions removed to provided remaining portions 14′ covering the lands 32 of the bipolar plate leaving the channels 34 of the bipolar plate 8 uncovered and exposed, as shown in FIG. 8. Again, the above described types of work may now be performed on the exposed portion of the bipolar plate.

Referring now to FIG. 9, a coating 28, such as a hydrophilic coating 28 is deposited over the remaining portion 14′ of the photoresist and the exposed potions 34 of the bipolar plate 8. Again, the coating may be depositing by spraying, brushing, rolling, printing, dipping, physical vapor deposition, chemical vapor deposition or plasma assisted vapor deposition. Thereafter, the coating 28 may be cured and the remaining portions 14′ of the photoresist stripped along with any coating covering the remaining portions 14′ of the photoresist to leave the coating 28 only in the channels 34 of the bipolar plate 8.

When the terms “over”, “overlying”, “overlies” or the like are used herein with respect to the relative position of layers to each other such shall mean that the layers are in direct contact with each other or that another layer or layers may be interposed between the layers.

The description of the invention is merely exemplary in nature and, thus, variations that do not depart from the gist of the invention are intended to be within the scope of the invention. Such variations are not to be regarded as a departure from the spirit and scope of the invention.

What is claimed is:

1. A process comprising:
depositing a mask having openings therethrough over portions of a substrate for use in a fuel cell, the mask leaving portion of the substrate exposed;
performing work on the exposed portions of the substrate.

2. A process as set forth in claim 2 wherein the substrate comprises a metal or an electrically conductive composite material.

3. A process as set forth in claim 1 wherein the work comprises at least one of cleaning, etching, pitting, ion implanting, bombarding, doped, blasting or coating the exposed portion of the substrate.

4. A process as set forth in claim 1 wherein the work comprises depositing a coating over the exposed portion of the substrate.

5. A process as set forth in claim 4 wherein the depositing of the coating over the exposed portions of the substrate comprises flowing the coating through the openings in the mask.

6. A process as set forth in claim 1 wherein the work comprises depositing a coating over the mask and over the exposed portions of the substrate and curing the coating.

7. A process as set forth in claim 6 further comprising removing the mask and the portion of the cured coating over the mask, leaving the cured coating only over the exposed portions of the substrate.

8. A process as set forth in claim 7 wherein the mask is a hard mask comprising at least one of a metal, polymeric material or a magnetized material.

9. A process as set forth in claim 7 wherein the mask comprises a photoresist material.

10. A process as set forth in claim 9 wherein the removing the mask comprises stripping the mask off of the substrate.

11. A process as set forth in claim 7 wherein the substrate is substantially flat prior to depositing the mask, and after removing the mask, forming the substrate into a bipolar plate having lands and channels.

12. A process as set forth in claim 1 wherein the work performed comprises depositing a coating comprises spraying, brushing, rolling, printing, dipping, physical vapor deposition, chemical vapor deposition or plasma assisted chemical vapor deposition.

13. A process comprising:
depositing a photoresist mask material over a bipolar plate having lands and channels, and wherein the mask covers the lands and channels;
removing portions of the photoresist material over the channels;
and performing work on the channels of the bipolar plate.

14. A process as set forth in claim 13 wherein the work comprises coating comprising depositing a coating over the mask and over the channel of the bipolar plate and curing the coating.

15. A process as set forth in claim 13 wherein the work comprises at least one of cleaning, etching, pitting, ion implanting, bombarding, doped, blasting or coating the exposed portion of the surface of the bipolar plate defining the channels.

16. A process comprising:
depositing a photoresist mask material over a bipolar plate having lands and channels, and wherein the mask covers the lands and channels;
removing portions of the photoresist material over the channels;
depositing a coating over the mask and the channels;
curing the coating and removing the remaining portions of the mask and the cured coating over the mask to leave the coating in the channels.

17. A process as set forth in claim 16 wherein the bipolar plate comprises a metal or an electrically conductive composite material.

18. A process as set forth in claim 16 wherein the depositing a coating comprises spraying, brushing, rolling, printing, dipping, physical vapor deposition, chemical vapor deposition of plasma assisted chemical vapor deposition.

19. A process as set forth in claim 16 wherein the mask is a hard mask comprising at least one of a metal, polymeric material or a magnetized material.

20. A process as set forth in claim 16 wherein the mask comprises a photoresist material.

21. A process as set forth in claim 20 wherein the removing the mask comprises stripping the mask off of the substrate.

22. A process comprising:
depositing a photoresist mask material over a bipolar plate having lands and channels;
removing portions of the photoresist material over selective portions of the bipolar plate leaving portions of the bipolar plate exposed;
depositing a coating over the mask and the channels;
curing the coating and removing the remaining portions of the mask and the cured coating over the mask to leave the coating over the previously exposed portions of the bipolar plate.
